(19) United States
(12) Patent Application Publication
(10) Pub. No.: US 2004/0244949 A1
(43) Pub. Date: Dec. 9, 2004

(54) Temperature controlled shield ring

(75) Inventor: Steven T. Fink, Mesa, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 10/809,436

(22) Filed: Mar. 26, 2004

Related U.S. Application Data
(60) Provisional application No. 60/474,249, filed on May 30, 2003.

(51) Int. Cl. F28F 7/00; F28F 13/00; C23C 16/00; H01L 21/302; H01L 21/461

(52) U.S. Cl. 165/80.5; 165/135; 438/731

(57) ABSTRACT

A method and apparatus for transferring heat from an outer edge of a substrate holder to a temperature-controlled shield ring surrounding the substrate in a plasma reactor. Additionally, heat may be transferred from an edge of the substrate to the shield ring as well.

### CROSS REFERENCE TO RELATED APPLICATION

This application claims priority to and is related to U.S. Provisional Application Ser. No. 60/474,249, filed on May 30, 2003. The contents of which are incorporated herein by reference.

### BACKGROUND OF THE INVENTION

1. Field of the Invention

The present invention relates to the management of heat removal during substrate processing, and more particularly to a temperature-controlled element surrounding a substrate holder and configured to transfer heat from an exterior edge of the substrate holder in a controllable manner.

2. Discussion of the Background

Many substrate manufacturing processes involve placing a substrate on the top surface of a substrate holder and subsequently processing the substrate in a plasma environment. During these processes, heat generated in the process is transferred to the substrate. This transfer can happen quickly, and this heat must also be quickly removed. Timely heat removal allows the substrate temperature to remain at predetermined levels for the particular process. Additionally, conventional processing systems utilize at least one of a focus ring (to affect the processing at the substrate edge) and a shield ring (to protect the outer edge of the substrate holder from the processing environment) surrounding a peripheral edge of the substrate. Since the focus ring and/or shield ring simply rest atop the substrate holder, they are often thermally decoupled from the temperature-controlled substrate holder. As a result, their exposure to a processing plasma, or other heat source, in the processing system leads to elevated temperatures which can affect the edge temperature of the substrate due to conductive and/or radiative thermal transport.

Heat transfer is important in the manufacture of substrates because imbalances in the temperature of a substrate during manufacturing result in differing properties across the substrate, thus making the use of such substrates more difficult and costly. The more accurately that heat transfer can be controlled, the faster the substrate manufacturing process can proceed with expectations of high quality output.

Known attempts to control the temperature of a substrate during manufacture have been accomplished primarily through two main systems/methods. The first uses backside cooling gas, and the second uses temperature controlled fluid circulation through internal passages in a substrate holder upon which the substrate rests during the manufacturing process.

In backside gas supply systems, heat transfer between the substrate and the substrate holder can be improved by supplying a heat transfer gas to the micro-gap residing between the backside of the substrate and the upper surface of the substrate holder. The presence of the heat transfer gas at a pre-specified pressure within this micro-gap can improve the thermal conductivity of the contact between the substrate and the substrate holder. The heat transferred between the substrate and the substrate holder is then transferred to a temperature controlled fluid, which circulates through passages in the substrate holder.

Excessive substrate temperature can damage structures on the substrate. Generally, in the absence of an effective heat transfer mechanism, the process must be operated at a lower power level or in an interrupted manner. Additionally, spatial variations in temperature through the substrate can lead to non-uniform processing of the substrate. For example, the substrate temperature can exhibit a non-uniform distribution radially from the center of the substrate toward its edge. This is due in part to a non-uniform heat flux to the substrate, and a non-uniform heat removal from the substrate. For example, oftentimes, the edge of the substrate holder can reach elevated temperatures and, in turn, affect the edge temperature of the substrate.

### SUMMARY OF THE INVENTION

It is an object of the present invention to provide both a method and an apparatus to reduce heat build-up near an outer edge of a substrate holder such that the substrate holder maintains a substantially similar temperature across its surface during the manufacturing process.

It is an object of the present invention to provide both a method and an apparatus to remove heat from an outer edge of a substrate being processed such that the substrate maintains a substantially similar temperature across its surface during the manufacturing process.

Another object of the present invention is to provide both a method and an apparatus to reduce heat build-up near an outer edge of a substrate holder such that the temperature in various parts of the substrate holder is effectively controlled to be different, thereby obtaining different properties in different parts of the substrate during the manufacture of such substrate.

Another object of the present invention is to provide both a method and an apparatus to remove heat from a substrate such that the temperature in various parts of the substrate is effectively controlled to be different, thereby obtaining different properties in different parts of the substrate during the manufacture of such substrate.

At least one object of the present invention is addressed by a method and an apparatus configured to reduce heat build-up near an outer edge of a substrate holder by utilizing a temperature-controlled shield ring assembly. In one such embodiment, the shield ring can be attached to the substrate holder without requiring additional mounting hardware. Such a capability allows the use of at least one embodiment of the present invention with existing substrate manufacturing facilities.

At least one object of the present invention is addressed by a method and an apparatus configured to remove heat from a substrate by utilizing a temperature-controlled shield ring assembly. In one such embodiment, the shield ring can be attached to the substrate holder without requiring additional mounting hardware. Such a capability allows the use of at least one embodiment of the present invention with existing substrate manufacturing facilities.

### BRIEF DESCRIPTION OF THE DRAWINGS

The above, as well as other advantages of the present invention, will become readily apparent to those skilled in the art from the following detailed description of the preferred embodiment when considered in the light of the accompanying drawings in which:

FIG. 1 is a cross-sectional view of a plasma processing system for use with the temperature-controlled shield ring of the present invention; and

FIG. 2 is a broken sectional view of a substrate holder and an apparatus for practicing the process of temperature control of a substrate which includes a shield ring assembly.

### DESCRIPTION OF THE PREFERRED EMBODIMENT

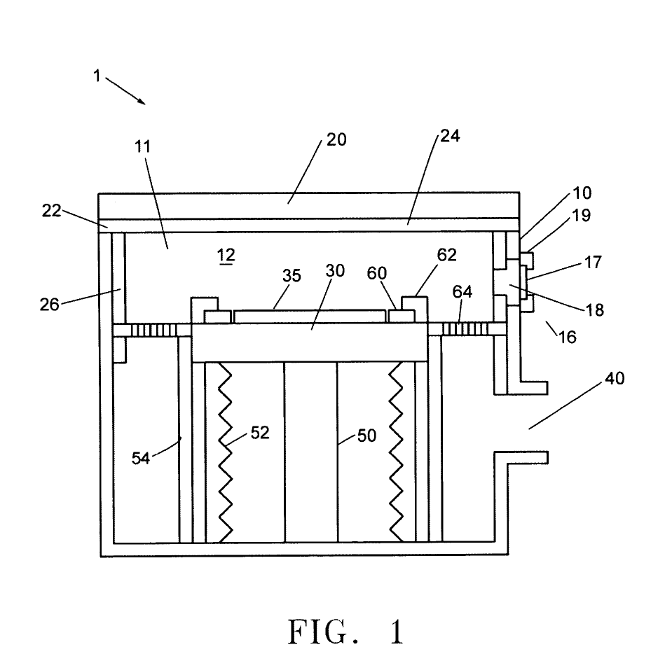

While those skilled in the art would recognize that there are a variety of ways to implement the present invention, an illustrative embodiment is shown in FIG. 1.

According to an embodiment of the present invention, a plasma processing system 1 comprises a plasma processing chamber 10, an upper assembly 20, an upper electrode 22, a substrate holder 30 for supporting a substrate 35, and a pumping duct 40 coupled to a vacuum pump (not shown) for providing a reduced pressure atmosphere 11 in plasma processing chamber 10. Plasma processing chamber 10 can facilitate the formation of a processing plasma in a process space 12 adjacent substrate 35. The plasma processing system 1 can be configured to process various substrates (i.e., 200 mm substrates, 300 mm substrates, or larger).

In the illustrated embodiment, upper electrode 22 comprises an electrode plate 24 with a deposition shield 26. In an alternate embodiment, upper assembly 20 can comprise at least one of a cover, a gas injection assembly, and an upper electrode impedance match network. For example, the upper electrode 22 can be coupled to an RF source. In another alternate embodiment, the upper assembly 20 comprises a cover and an upper electrode 22, wherein the upper electrode is maintained at an electrical potential equivalent to that of the plasma processing chamber 10. For example, the plasma processing chamber 10, the upper assembly 20, and the upper electrode 22 can be electrically connected to ground potential.

Plasma processing chamber 10 can, for example, further comprise an optical viewport 16. Optical viewport 16 can comprise an optical window 17 coupled to the backside of an optical window deposition shield 18, that can be coupled to deposition shield 26, and an optical window flange 19 can be configured to couple optical window 17 to the optical window deposition shield 18. Sealing members, such as O-rings, can be provided between the optical window flange 19 and the optical window 17, between the optical window 17 and the optical window deposition shield 18, and between the optical window deposition shield 18 and the plasma processing chamber 10. Optical viewport 16 can, for example, permit monitoring of optical emission from the processing plasma in process space 12.

Substrate holder 30 can, for example, further comprise a vertical translational device 50 surrounded by a bellows 52 coupled to the substrate holder 30 and the plasma processing chamber 10, and configured to seal the vertical translational device 50 from the reduced pressure atmosphere 11 in plasma processing chamber 10. Additionally, a bellows shield 54 can, for example, be coupled to the substrate holder 30 and configured to protect the bellows 52 from the processing plasma. Substrate holder 10 can, for example, further be coupled to at least one of a focus ring 60, and a shield ring 62. Furthermore, a baffle plate 64 can extend about a periphery of the substrate holder 30.

Substrate 35 can be, for example, transferred into and out of plasma processing chamber 10 through a slot valve (not shown) and chamber feed-through (not shown) via robotic substrate transfer system where it is received by substrate lift pins (not shown) housed within substrate holder 30 and mechanically translated by devices housed therein. Once substrate 35 is received from substrate transfer system, it is lowered to an upper surface of substrate holder 30.

Substrate 35 can be, for example, affixed to the substrate holder 30 via an electrostatic clamping system. Furthermore, substrate holder 30 can, for example, further include a cooling system including a re-circulating coolant flow that receives heat from substrate holder 30 and transfers heat to a heat exchanger system (not shown), or when heating, transfers heat from the heat exchanger system. Moreover, gas can, for example, be delivered to the back-side of substrate 35 via a backside gas system to improve the gas-gap thermal conductance between substrate 35 and substrate holder 30. Such a system can be utilized when temperature control of the substrate is required at elevated or reduced temperatures. In other embodiments, heating elements, such as resistive heating elements, or thermo-electric heaters/coolers can be included.

In the illustrated embodiment, shown in FIG. 1, substrate holder 30 can comprise an electrode through which RF power is coupled to the processing plasma in process space 12. For example, substrate holder 30 can be electrically biased at a RF voltage via the transmission of RF power from a RF generator (not shown) through an impedance match network (not shown) to substrate holder 30. The RF bias can serve to heat electrons to form and maintain plasma. In this configuration, the system can operate as a reactive ion etch (RIE) reactor, wherein the chamber and upper gas injection electrode serve as ground surfaces. A typical frequency for the RF bias can range from 1 MHz to 100 MHz and is preferably 13.56 MHz. RF systems for plasma processing are well known to those skilled in the art.

Alternately, the processing plasma formed in process space 12 can be formed using a parallel-plate, capacitively coupled plasma (CCP) source, an inductively coupled plasma (ICP) source, any combination thereof, and with and without DC or AC magnet systems. Alternately, the processing plasma in process space 12 can be formed using electron cyclotron resonance (ECR). In yet another embodiment, the processing plasma in process space 12 is formed from the launching of a Helicon wave. In yet another embodiment, the processing plasma in process space 12 is formed from a propagating surface wave.

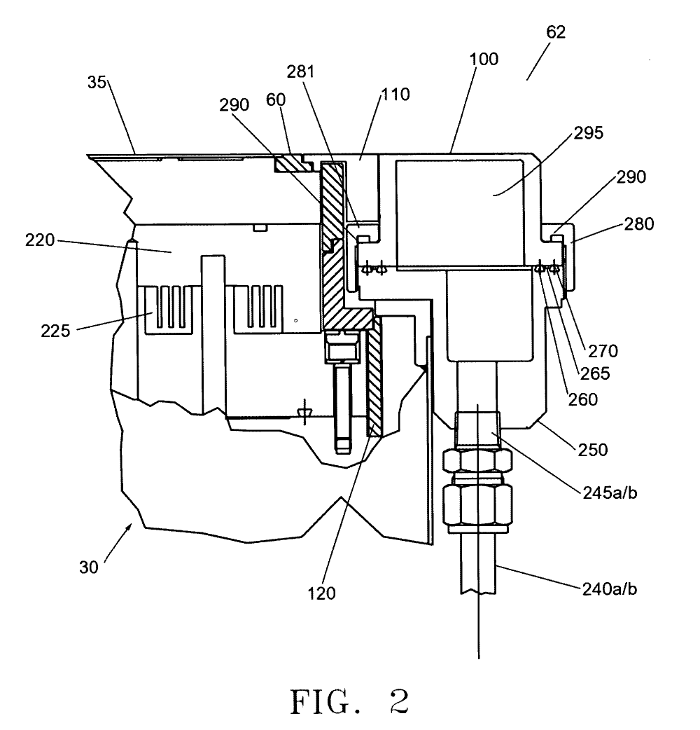

During processing, ion bombardment of surfaces exposed to the plasma, such as the upper surface of the substrate, can lead to a substantial heat flux at these surfaces. Therefore, in order to maintain a constant temperature, an equivalent cooling heat flux must be imposed. For example, as shown in FIG. 2, a chuck block 220 underneath the substrate 35 contains a coolant passage 25 for the transmission of a coolant within the chuck block 220, in order to remove heat from the substrate holder 30, and the substrate 35 via thermal coupling through the micro-gap between the substrate holder 30 and the substrate 35.

By maintaining a pre-specified temperature for the substrate holder 30 relative to the substrate 35, heat from the substrate 35 is conducted to the substrate holder 30, thereby balancing the heat deposited in the substrate due to exposure to the plasma during the manufacturing process. A shield ring 62 is rested on a shoulder of the substrate holder 30 with no fasteners needed to maintain the position of the shield ring 62. The shield ring 62 is adjacent to an insulating element 120 for a substantial portion of the height of the shield ring 62. Heat is absorbed from the plasma by a cap 100, wherein a coolant is contained and circulated within an internal passage 295 of the cap 100. The coolant receives heat energy conducted from the plasma. The cap 100 protects the other components of the shield ring 62 from the effects of the manufacturing process.

In an alternate embodiment, a heat conducting element 110 is also configured to receive heat from the substrate 35 through focus ring 60. In such an embodiment, heat conducting contact is made from the substrate 35 to the cap 100 of the focus ring 60 by means of the heat conducting element 110 and focus ring 60 contacting both the substrate 35 and the cap 100.

The temperature of the coolant in the internal passage 295 will rise from the absorption of heat energy from the substrate 35, heat conducting element 110, cap 100 and the other elements directly and indirectly exposed to the plasma. Such coolant is therefore transmitted through the shield ring 62 and out through the coolant return port 245a housed in a plenum adapter 250. After passing through the coolant return port 245a, the coolant is transmitted through the coolant return hose 240a to a coolant temperature control assembly (not shown) where the coolant exchanges thermal energy with a heat exchanger to reduce its temperature prior to being returned to the shield ring 62 via the coolant supply hose 245b and coolant supply port 245b.

In one embodiment, the apparatus of the present invention comprises: an annular lower metal plenum adapter ring in which the bottom surface is configured to rest on a shelf provided on the substrate holder; and supply and return ports, connected to the lower surface of the adapter ring, for temperature controlled dielectric fluid connections; the ports connecting internal process chamber connections to dielectric fluid supply and return lines.

Preferably, the bottom surface of the cap 100 is flat, so that it can conveniently mate with the upper surface of the plenum adapter ring. The surface finish of the bottom surface of the cap is sufficient to ensure fluid and vacuum seals operate properly.

Annular nuts 280 and 281 secure the cap to the plenum adapter ring, and a cushioning element such as an o-ring 270 is used with each fastener to protect the cap from point loading damage.

Internal process chamber coolant lines connecting to the supply and return ports of the temperature controlled focus ring assembly are connected to corresponding feed-thrus located in the process chamber. External coolant lines connecting to these feed-thrus also connect to the remote dielectric temperature controller assembly. The internal coolant lines connect to the focus ring itself, which resides adjacent the substrate during the manufacturing process to dissipate heat from the side of the substrate.

The annular nuts can all be torqued with sufficient force to ensure that all seals are effective.

Between the dielectric seal 260 and the vacuum seal 270 is a leak check port 265 that vents outside the plasma reactor to indicate the presence of coolant or vacuum leaks.

In one embodiment, two annular nuts 280 and 281 are is used to fasten the cap 100 to the plenum adapter 250. The inner and outer radial surfaces of the cap 100 and the plenum adapter 250 are threaded to accept such mating threaded rings or nuts.

The present invention provides a process for controlling the temperature of a substrate during such substrate's manufacture comprising the steps of: (1) placing a focus ring around the substrate and the substrate holder upon which the substrate resides during the substrate manufacturing process, (2) circulating a coolant (e.g., a dielectric fluid such as FLUORINERT) into, through and out of, the focus ring to dissipate heat absorbed from the plasma, and (3) additionally circulating coolant into, through and out of the substrate holder to dissipate heat build-up in the substrate holder 35. In an alternate embodiment, the temperature of the coolant can additionally be controlled by connecting the focus ring to a remote dielectric fluid temperature controller assembly (e.g., via supply and return lines), thereby increasing temperature uniformity.

Additionally, liquid nitrogen and/or helium and other chemicals can also be used in place of, or in addition to, the dielectric fluid to perform the heat dissipation in the proposed method and apparatus. The process can be tunable so that the substrate can be maintained at a similar temperature across the substrate or different parts of the substrate may be maintained at different temperatures based upon the maintenance of optimal conditions for the particular manufacturing process.

The method may also be used to obtain varied results in manufacturing by tunably controlling the temperature in various parts of a substrate undergoing manufacture. Such tunability may be accomplished by circulating dielectric or other coolant fluid in different portions of the focus ring and substrate holder. Such tunability allows for the maintenance of differing properties at different points in the substrate during the manufacturing process.

The method and apparatus of the invention allows for the production of substrates more efficiently, i.e., at either higher rates or with higher quality of the final product, or some combination thereof.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

1. A temperature-controlled shield ring, comprising:
a shield ring for surrounding a substrate holder; and
coolant passageways within a portion of the shield ring for controlling a temperature of the shield ring by passing a coolant through the coolant passageways.

2. The temperature-controlled shield ring according to claim 1, wherein the shield ring comprises:
a cap; and
a heat conducting element connected between the cap and a location where a substrate would rest during processing, the heat conducting element configured to transfer heat from the substrate to the cap.

3. The temperature-controlled shield ring according to claim 2, wherein the cap comprises a ceramic material.

4. The temperature-controlled shield ring according to claim 2, wherein the cap comprises anodized aluminum.

5. The temperature-controlled shield ring according to claim 1, wherein the coolant comprises a dielectric fluid.

6. The temperature-controlled shield ring according to claim 1, further comprising an insulator housed between the shield ring and the substrate holder.

7. The temperature-controlled shield ring according to claim 1, further comprising an adapter for connecting to a cooling system of the substrate to provide coolant exchange between the shield ring and the substrate holder.

8. The temperature-controlled shield ring according to claim 1, wherein the shield ring is configured to attach to the substrate holder without the use of fasteners.
